(19) United States
(12) Patent Application Publication
(10) Pub. No.: US 2026/0068117 A1
(43) Pub. Date: Mar. 5, 2026

(54) MEMORY STRUCTURE AND MANUFACTURING METHOD THEREOF

(71) Applicant: TAIWAN SEMICONDUCTOR MANUFACTURING COMPANY LTD., HSINCHU (TW)

(72) Inventors: WEI-CHEN CHU, TAICHUNG CITY (TW); CHIA-TIEN WU, TAICHUNG CITY (TW); CHIA CHEN LEE, TAIPEI CITY (TW); SHU-YUN KU, HSINCHU COUNTY (TW)

(21) Appl. No.: 18/817,273

(22) Filed: Aug. 28, 2024

(51) Int. Cl. H10B 10/00; H01L 29/423

(52) U.S. Cl. CPC H10B 10/12; H10D 30/6735

(57) ABSTRACT

A memory structure is provided. The memory structure includes a first pull-up transistor in a first active region, a second pull-up transistor in a second active region parallel to and separated from the first active region, and an electrode overlapping the first and second active regions and configured to electrically connect a gate structure of the second pull-up transistor to a drain region of the first pull-up transistor. The electrode is formed in a metal layer closest to the first and second active regions.

### BACKGROUND

Advances in the integrated circuit (IC) industry have resulted in smaller and more complex circuits than the previous generation, which, however, have commensurately increased complexity of processing and manufacturing. In the course of IC evolution, functional density (i.e., the number of interconnected devices per chip area) has generally increased while geometric size (i.e., the smallest component that can be created using a fabrication process) has decreased.

Static Random Access Memory (SRAM) is commonly used in integrated circuits. SRAM cells have the advantage of being able to store data with no need to refresh. With increasingly demanding requirements on the speed of integrated circuits, read and write speeds of SRAM cells have become critical. Therefore, it is important to provide a memory structure for the SRAM cells to improve density as cell size continues to be reduced.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, the dimensions of the various features may be arbitrarily increased or reduced for clarity of discussion.

FIG. 1 is a block diagram of a memory cell, in accordance with some embodiments of the disclosure.

FIG. 2 is a cross section of a semiconductor structure including the memory cell of FIG. 1, in accordance with some embodiments of the disclosure.

FIG. 3 illustrates a layout of a memory structure including the memory cells, in accordance with some embodiments of the disclosure.

FIGS. 4A and 4B illustrate the features in different levels of the layout of the memory cells in FIG. 3, in accordance with some embodiments of the disclosure.

FIG. 5 is a cross section of the semiconductor structure including the pull-up transistors in FIG. 3, in accordance with some embodiments of the disclosure.

FIG. 6 illustrates the metal lines and electrodes in the lowest metal layer of FIG. 3, in accordance with some embodiments of the disclosure.

FIG. 7 illustrates a layout of a memory structure including the memory cells, in accordance with some embodiments of the disclosure.

FIGS. 8A and 8B illustrate the features in different levels of the layout of the memory cells in FIG. 7, in accordance with some embodiments of the disclosure.

FIG. 9 illustrates the metal lines and the electrodes in the lowest metal layer of FIG. 7, in accordance with some embodiments of the disclosure.

FIGS. 10A and 10B illustrate the formation of the electrodes, in accordance with some embodiments of the disclosure.

FIG. 11 illustrates a layout of a memory structure including the memory cells, in accordance with some embodiments of the disclosure.

FIGS. 12A and 12B illustrate the features in different levels of the layout of the memory cells in FIG. 11, in accordance with some embodiments of the disclosure.

FIG. 13 illustrates the metal lines and the electrodes in the lowest metal layer of FIG. 11, in accordance with some embodiments of the disclosure.

### DETAILED DESCRIPTION

The following disclosure provides many different embodiments, or examples, for implementing different features of the provided subject matter. Specific examples of components and arrangements are described to simplify the disclosure. These are, of course, merely examples and are not intended to be limiting. For example, the formation of a first feature over or on a second feature in the description that follows may include embodiments in which the first and second features are formed in direct contact, and may also include embodiments in which additional features may be formed therebetween. In addition, the present disclosure may repeat reference numerals and/or letters in the various examples. This repetition is for the purpose of simplicity and clarity and does not in itself dictate a relationship between the various embodiments and/or configurations discussed.

While embodiments of the present disclosure are discussed in detail, it should be appreciated that the present disclosure provides many applicable inventive concepts that can be embodied in a wide variety of specific contexts. The specific embodiments discussed are merely illustrative and do not limit the scope of the disclosure.

Further, spatially relative terms, such as “beneath,” “below,” “lower,” “above,” “upper,” “lower,” “left,” “right” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

Various semiconductor structures in integrated circuits (ICs) are provided in accordance with various exemplary embodiments. Some variations of some embodiments are discussed. Throughout the various views and illustrative embodiments, like reference numbers are used to designate like elements.

The nanostructure transistor (e.g. nanosheet transistor, nanowire transistor, multi-bridge channel, nano-ribbon FET, gate all around (GAA) transistor structures) described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

According to the embodiments of the present disclosure, the electrodes in the lowest metal layer are configured as oblique connections, to provide local connections for storage nodes within a SRAM cell. The oblique connection is implemented by a two-dimensional (2D) metal connection, an electrode plate with diagonally cut, or a slanting line, so as to increase the SRAM density enhancement for pitch and reduced cell height.

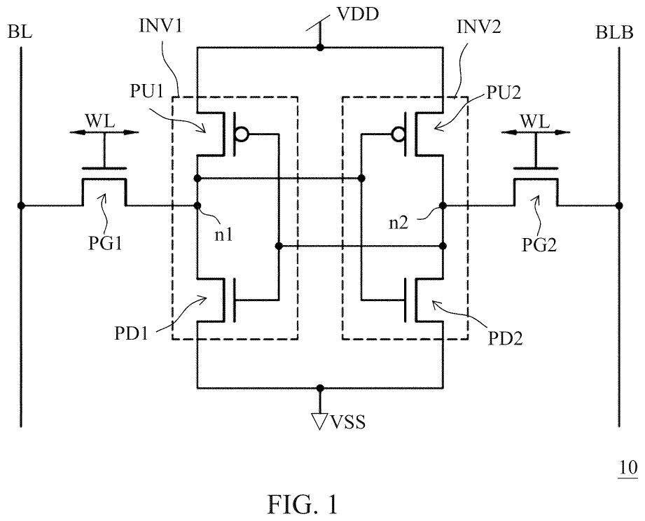

FIG. 1 is a block diagram of a memory cell 10, in accordance with some embodiments of the disclosure. In this embodiment, the memory cell 10 is a single-port static random access memory (SRAM) bit cell. A memory array formed by the memory cells 10 in rows and columns can be implemented in an integrated circuit (IC), and can be accessed by a controller. The controller may be implemented in the same or another IC.

The memory cell 10 includes a pair of inverters INV1 and INV2 cross-coupled between the nodes (or storage nodes) n1 and n2, forming a latch, a pass-gate transistor PG1 coupled between a bit line BL and node n1, and a pass-gate transistor PG2 coupled between a complementary bit line BLB and node n2. The complementary bit line BLB is complementary to the bit line BL. The gates of the pass-gate transistors PG1 and PG2 are coupled to the same word-line WL. In some embodiments, the pass-gate transistors PG1 and PG2 are NMOS transistors.

The inverter INV1 includes a pull-up transistor PU1 and a pull-down transistor PD1. The pull-up transistor PU1 is a PMOS transistor, and the pull-down transistor PD1 is an NMOS transistor. The drains of the pull-up transistor PU1 and the pull-down transistor PD1 are coupled to the node n1 connected to the pass-gate transistor PG1. The gates of the pull-up transistor PU1 and the pull-down transistor PD1 are coupled to the node n2 connected to the pass-gate transistor PG2. Furthermore, the source of the pull-up transistor PU1 is coupled to the positive power supply node VDD, and the source of the pull-down transistor PD1 is coupled to a ground VSS.

Similarly, the inverter INV2 includes a pull-up transistor PU2 and a pull-down transistor PD2. The pull-up transistor PU2 is a PMOS transistor, and the pull-down transistor PD2 is an NMOS transistor. The drains of the pull-up transistor PU2 and the pull-down transistor PD2 are coupled to the node n2 connected to the pass-gate transistor PG2. The gates of the pull-up transistor PU2 and the pull-down transistor PD2 are coupled to the node n1 connected to the pass gate transistor PG1. Furthermore, the source of the pull-up transistor PU2 is coupled to the positive power supply node VDD, and the source of the pull-down transistor PD2 is coupled to the ground VSS.

In some embodiments, the pass-gate transistors PG1 and PG2, the pull-up transistors PU1 and PU2, and the pull-down transistors PD1 and PD2 of the memory cell 10 are selected from a group consisting of a finFET structure, a vertical gate all around (GAA), a horizontal GAA, fork-sheet structure, a nano wire, a nano sheet, or a combination thereof.

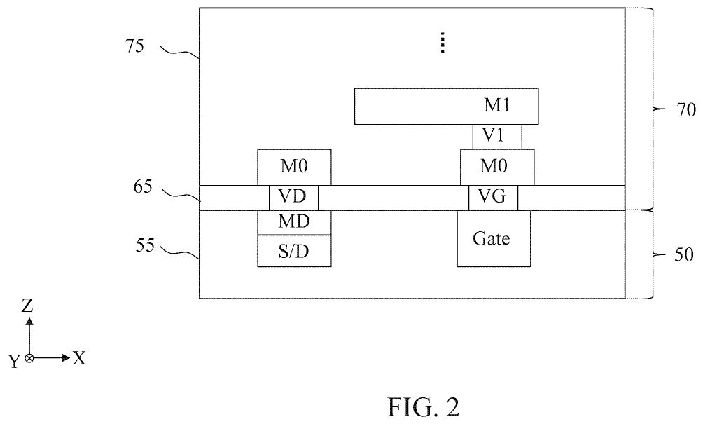

FIG. 2 is a cross section of a semiconductor structure including the memory cell 10 of FIG. 1, in accordance with some embodiments of the disclosure. The semiconductor structure has a device layer 50 (also referred to as a device region) and an interconnect structure 70. The device layer 50 includes a substrate 55 and is where transistors and main features such as the gate, channel, source/drain region, contact features, and the transistors (e.g., the N-type transistors and the P-type transistors) are located. Source/drain region(s) may refer to a source or a drain, individually or collectively, depending on context.

The interconnect structure 70 is formed over the device layer 50. The interconnect structure 70 includes an inter-layer dielectric (ILD) layer 65, an inter-metal dielectric (IMD) layer 75, the connecting features (e.g., the vias VG, VD and V1), and the metal lines M0 and M1. The metal line M0 is formed in the lowest metal layer in the interconnect structure 70, and the lowest metal layer is the metal layer closest to the device layer 50. The vias and metal lines in the IMD layer 75 are electrically coupled to various transistors and/or components (e.g., the gate, source/drain features, resistors, capacitors, and/or inductors) of the device layer 50, such that the various devices and/or components can operate as needed. It should be noted that there may be more vias and metal lines in the IMD layer 75 for connections. Furthermore, the IMD layer 75 may be multilayered. In some embodiments, the via VG is connected to the gate structures (labeled as Gate) of the transistors, and the via VG is also referred to as the gate via. In some embodiments, the via VD is connected to the source/drain contacts (labeled as MD) of the transistors, and the source/drain contacts are formed over the source/drain region (labeled as S/D) of the transistors.

The ILD layer 65 and IMD layer 75 may include one or more dielectric layers including dielectric materials, such as tetraethylorthosilicate (TEOS) oxide, undoped silicate glass, or doped silicon oxide such as borophosphosilicate glass (BPSG), fluoride-doped silica glass (FSG), phosphosilicate glass (PSG), boron doped silicon glass (BSG), a low-k dielectric material, other suitable dielectric material, or a combination thereof.

The materials of the source/drain contacts, the connecting features and the metal lines are selected from a group consisting of titanium (Ti), titanium nitride (TiN), tantalum (Ta), tantalum nitride (TaN), titanium aluminum nitride (TiAlN), tungsten nitride (WN), tungsten (W), cobalt (Co), molybdenum (Mo), ruthenium (Ru), platinum (Pt), aluminum (Al), copper (Cu), other conductive materials, or a combination thereof.

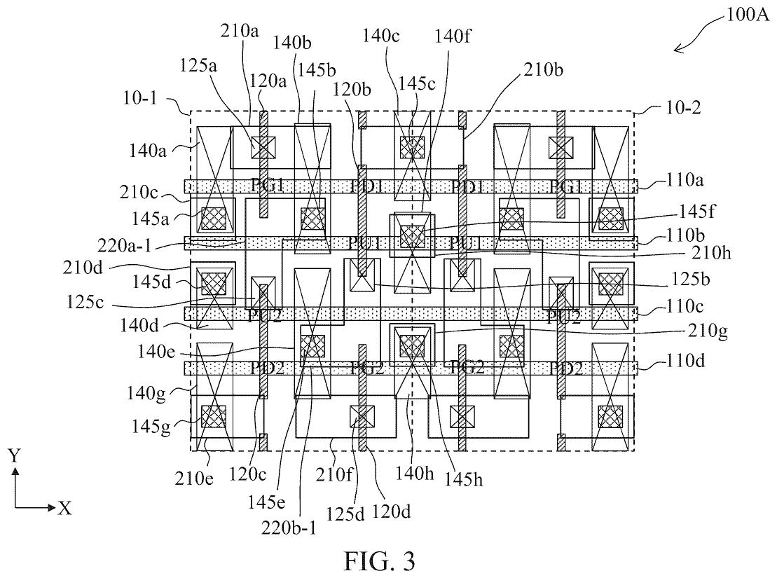

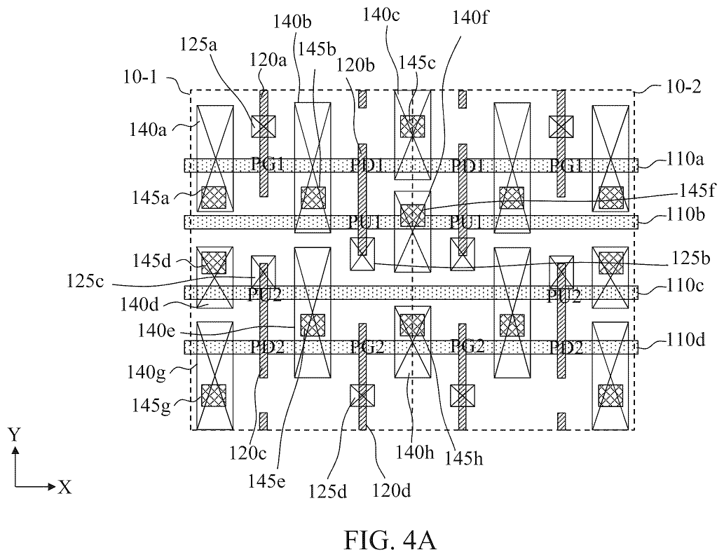

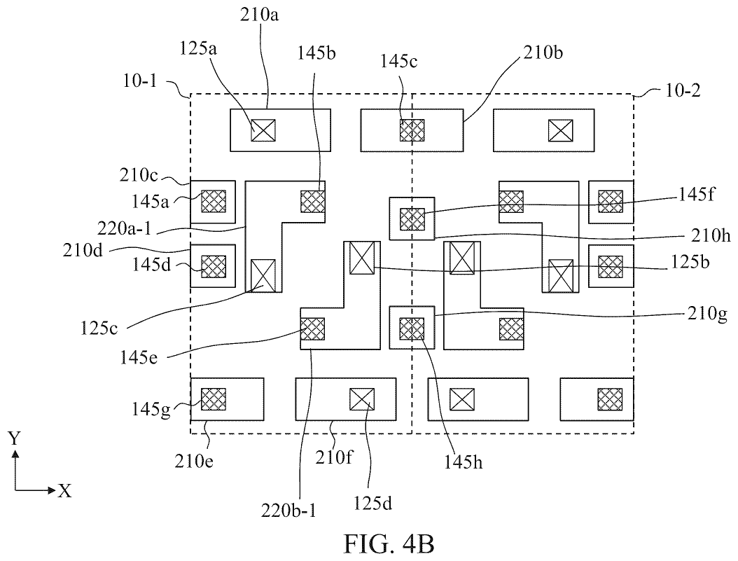

FIG. 3 illustrates a layout of a memory structure 100A including the memory cells 10-1 and 10-2, in accordance with some embodiments of the disclosure. FIG. 4A illustrates the features under a lowest metal layer and FIG. 4B illustrates the features of the interconnect structure (e.g., the interconnect structure 70 of FIG. 2) in the layout of the memory cells 10-1 and 10-2 of FIG. 3, in accordance with some embodiments of the disclosure. In this embodiment, the memory cells 10-1 and 10-2 are the single-port SRAM bit cell shown in FIG. 1. Furthermore, an outer boundary of each of the memory cells 10-1 and 10-2 is illustrated using dashed lines.

The memory cells 10-1 and 10-2 are the adjacent memory cells 10 arranged in the same row of the memory array. In some embodiments, the two adjacent memory cells 10-1 and 10-2 are arranged in mirror symmetry along a Y-axis. Furthermore, an outer boundary of each of the memory cells 10-1 and 10-2 is illustrated using dashed lines, which mark a rectangular region with an X-pitch along the X-axis and a Y-pitch along the Y-axis, and the X-pitch is shorter than the Y-pitch. Since the memory cells 10-1 and 10-2 are symmetrical in layout, in order to simplify the description, only the features of layout in the memory cell 10-1 are detailed here.

In the memory cell 10-1, the pass-gate transistor PG1 and the pull-down transistor PD1 are formed in an active region 110a, and the pull-up transistor PU1 is formed in an active region 110b. The pull-up transistor PU2 is formed in an active region 110c, and the pass-gate transistor PG2 and the pull-down transistor PD2 are formed in an active region 110d. The active regions 110a through 110d extend along the X-axis. The active region 110b is disposed between the active regions 110a and 110c, and the active region 110c is disposed between the active regions 110b and 110d. In some embodiments, the active regions 110a through 110d have the same width along the Y-axis. In some embodiments, a width of the active regions 110a and 110d is different from a width of the active regions 110b and 110c. In some embodiments, the active regions 110a through 110d have the same pitch.

In some embodiments, each of the active regions 110a through 110d is formed by the nanostructures formed on the substrate. In some embodiments, the nanostructures may also be referred to as channels, channel layers, nanosheets, or nanowires. The nanostructures may include a semiconductor material, such as silicon, germanium, silicon carbide, silicon phosphide, gallium arsenide, gallium phosphide, indium phosphide, indium arsenide, and/or indium antimonide, silicon germanium (SiGe), SiPC, GaAsP, AlInAs, AlGaAs, GaInAs, GaInP, and/or GaInAsP. In some embodiments, the nanostructures include silicon for N-type GAA transistors. In other embodiments, the nanostructures include silicon germanium for P-type GAA transistors. In some embodiments, the nanostructures are all made of silicon, and the type of GAA transistors depend on work function metal layer wrapping around the nanostructures. Along the Y-axis, the memory cells 10-1 and 10-2 include less active regions to have highly capability for cell scaling.

The source/drain contacts 140a through 140h and the gate structures 120a through 120d extend along the Y-axis. The source/drain contacts 140a through 140h are configured to connect the source/drain regions of the transistors in the memory cell 10-1. Source/drain region(s) may refer to a source or a drain, individually or collectively dependent upon the context.

The gate structure 120a forms the pass-gate transistor PG1 with the active region 110a. The gate structure 120b forms the pull-up transistor PD1 with the active region 110a and forms the pull-up transistor PU1 with the active region 110b. The gate structure 120c forms the pull-up transistor PU2 with the active region 110c and forms the pull-down transistor PD2 with the active region 110d. The gate structure 120d forms the pass-gate transistor PG2 with the active region 110d. In some embodiments, the gate structures 120a and 120d are shared with the adjacent memory cells 10 in adjacent rows.

The gate structure 120a is electrically connected to the metal line 210a through the gate via 125a. The metal line 210a functions as a landing pad (or a landing line) of the word line WL for the memory cell 10-1. The gate structure 120b is electrically connected to the electrode 220b-1 through the gate via 125b. The electrode 220b-1 functions as a local connection of the node n2 in the memory cell 10-1, and no upper level interconnect structure is connected to the electrode 220b-1. The gate structure 120c is electrically connected to the electrode 220a-1 through the gate via 125c. The electrode 220a-1 functions as a local connection of the node n1 in the memory cell 10-1, and no upper level interconnect structure is connected to the electrode 220a-1. The gate structure 120d is electrically connected to the metal line 210f through the gate via 125d. The metal line 210f functions as a landing pad (or a landing line) of the word line WL for the memory cell 10-1. The metal line 210f is electrically connected to the metal line 210a through the interconnection structure (not shown) over the lowest metal layer. The electrode 220a-1 overlaps the gate structures 120a and 120c arranged in the same column, and the electrode 220b-1 overlaps the gate structures 120b and 120d arranged in the same column.

The source/drain contact 140a overlaps the active region 110a and corresponds to one source/drain feature of the pass-gate transistor PG1. The source/drain contact 140a is electrically connected to the metal line 210c through the via 145a. The metal line 210c functions as a landing pad of the bit line BL. The metal line 210c is electrically connected to the bit line BL of the other memory cells 10 through the interconnection structure (not shown) over the lowest metal layer. The source/drain contact 140b overlaps the active regions 110a and 110b and corresponds to another source/drain feature of the pass-gate transistor PG1 and the drain features of the pull-up transistor PU1 and the pull-down transistor PD1. In other words, the source/drain contact 140b is shared by the pass-gate transistor PG1, the pull-up transistor PU1 and the pull-down transistor PD1. The source/drain contact 140b is electrically connected to the electrode 220a-1 through the via 145b to connect to the gate structure 120c.

The source/drain contact 140c overlaps the active region 110a and corresponds to the source feature of the pull-down transistor PD1. The source/drain contact 140c is electrically connected to the metal line 210b through the via 145c. The metal line 210b functions as the VSS line (or VSS conductor) for the memory cell 10-1. The source/drain contact 140f overlaps the active region 110b and corresponds to the source feature of the pull-up transistor PU1. The source/drain contact 140f is electrically connected to the metal line 210h through the via 145f. The metal line 210h functions as the VDD line (or VDD conductor) for the memory cell 10-1.

The source/drain contact 140h overlaps the active region 110d and corresponds to one source/drain feature of the pass-gate transistor PG2. The source/drain contact 140h is electrically connected to the metal line 210g through the via 145h. The metal line 210g functions as a landing pad of the complementary bit line BLB. The metal line 210g is electrically connected to the complementary bit line BLB of the other memory cells 10 through the interconnection structure (not shown) over the lowest metal layer. The source/drain contact 140e overlaps the active regions 110c and 110d and corresponds to another source/drain feature of the pass-gate transistor PG2 and the drain features of the pull-up transistor PU2 and the pull-down transistor PD2. In other words, the source/drain contact 140e is shared by the pass-gate transistor PG2, the pull-up transistor PU2 and the pull-down transistor PD2. The source/drain contact 140e is electrically connected to the electrode 220b-1 through the via 145e to connect to the gate structure 120b.

The source/drain contact 140g overlaps the active region 110d and corresponds to the source feature of the pull-down transistor PD2. The source/drain contact 140g is electrically connected to the metal line 210e through the via 145g. The metal line 210e functions as the VSS line (or VSS conductor) for the memory cell 10-1. The source/drain contact 140d overlaps the active region 110c and corresponds to the source feature of the pull-up transistor PU2. The source/drain contact 140d is electrically connected to the metal line 210d through the via 145d. The metal line 210d functions as the VDD line (or VDD conductor) for the memory cell 10-1. The metal line 210d is electrically connected to the metal line 210h through the VDD interconnection structure (not shown) over the lowest metal layer. The metal line 210e is electrically connected to the metal line 210b through the VSS interconnection structure (not shown) over the lowest metal layer.

In such embodiment, the gate via 125c and the via 145b are not arranged in the same grid, i.e. in the same line along the X-axis. Similarly, the gate via 125b and the via 145e are not arranged in the same grid. Therefore, the vias 145b and 145e cannot act as a body contact (BCT) to connect the corresponding gate structure. The electrodes 220a-1 and 220b-1 are configured to provide oblique connections to increase SRAM density enhancement for pitch and reduced cell height. Furthermore, compared with using the slanting connecting feature (e.g., the via VD) as the local connection of the node n1 or n2 in the memory cell 10-1, no leakage occurs in the oblique connection of the lowest metal line in the memory structure 100A.

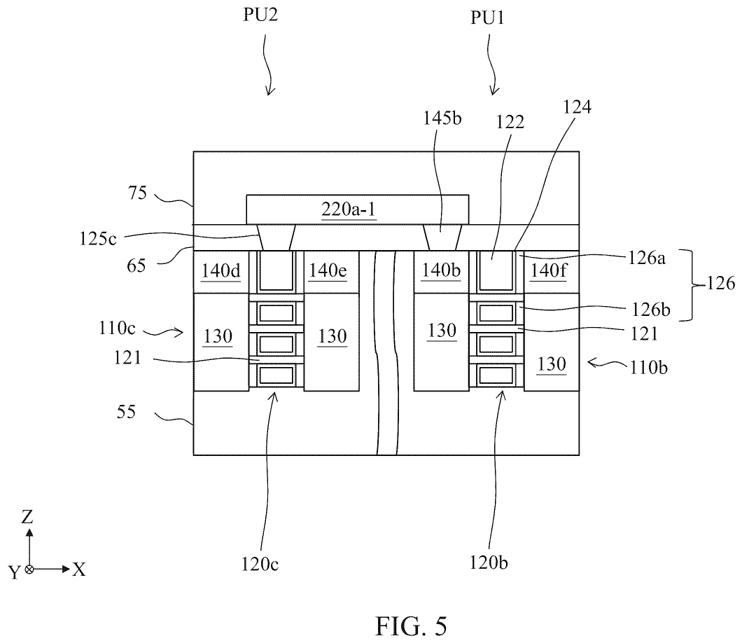

FIG. 5 is a cross section of the semiconductor structure including the pull-up transistors PU1 and PU2 in FIG. 3, in accordance with some embodiments of the disclosure. In FIG. 5, the active regions 110c and the 110b constructed by the nanostructures 121 and the source/drain features 130 are shown.

Each of gate structures 120b and 120c includes the nanostructures 121 extending along an X-axis and vertically arranged (or stacked) along a Z-axis. More specifically, the nanostructures 121 are spaced along the Z-axis. In some embodiments, the nanostructures 121 may also be referred to as channels, channel layers, nanosheets, or nanowires. The nanostructures 121 may include a semiconductor material, such as silicon, germanium, silicon carbide, silicon phosphide, gallium arsenide, gallium phosphide, indium phosphide, indium arsenide, and/or indium antimonide, silicon germanium (SiGe), SiPC, GaAsP, AlInAs, AlGaAs, GaInAs, GaInP, and/or GaInAsP. In some embodiments, the nanostructures 121 include silicon for N-type gate-all-around (GAA) field effect transistors (FETs). In some embodiments, the nanostructures 121 are all made of silicon, and the type of GAA transistors depend on work function metal layer wrapping around the nanostructures 121.

The gate dielectric layer 124 wraps around the nanostructures 121, and the gate electrode 122 wraps around the gate dielectric layer 124. The gate electrode 122 may include polysilicon or work function metal. The work function metal includes TiN, TaN, TiAl, TiAlN, TaAl, TaAlN, TaAlC, TaCN, WNC, Co, Ni, Pt, W, combinations thereof, or other suitable material. The gate dielectric layer 124 may include dielectric materials, such as silicon oxide, silicon nitride, silicon oxynitride, dielectric material(s) with high dielectric constant (high-k), or a combination thereof. Examples of high-k dielectric materials include TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfLaO, HfSiO, LaSiO, AlSiO, HfTaO, HfTiO, (Ba,Sr)TiO₃ (BST), Al₂O₃, Si₃N₄, oxynitrides (SiON), combinations thereof, or other suitable material.

The spacers 126 are on sidewalls of the gate structures 120b and 120c. The spacers 126 include the outer spacers 126a and the inner spacers 126b. The outer spacers 126a are over the nanostructures 121 and on top sidewalls of the gate structures 120b and 120c. The outer spacers 126a may include multiple dielectric materials and be selected from a group consist of SiO₂, Si₃N₄, carbon doped oxide, nitrogen doped oxide, porous oxide, air gap, or, or a combination thereof. The inner spacers 126b are between the nanostructures 121. In some embodiments, the inner spacers 126b may include a dielectric material having higher K value (dielectric constant) than the outer spacers 126a and be selected from a group consisting of silicon nitride (Si₃N₄), silicon oxide (SiO₂), silicon carbide (SiC), silicon oxycarbide (SiOC), silicon oxynitride (SiON), silicon oxycarbon nitride (SiOCN), air gap, or a combination thereof.

Each source/drain feature 130 is disposed between two adjacent gate structures and connects (or contacts) the nanostructures 121 of the transistors. Each source/drain feature 130 is shared by two adjacent gate structures. In some embodiments, the shared source/drain feature 130 may also be referred to as the common source/drain feature (or common source/drain region) of two adjacent transistors. The source/drain features 130 are formed by epitaxially-grown materials, which, in some embodiments, for the N-type transistors, may include SiP, SiC, SiPC, SiAs, Si, or a combination thereof.

The source/drain contacts 140d, 140e, 140b and 104f extending along the Y-axis are over and contact (or connect) the source/drain features 130. Furthermore, the silicide feature (not shown) is formed between the source/drain contacts 140d, 140e, 140b and 104f and the source/drain features 130. The silicide features may include titanium silicide (TiSi), nickel silicide (NiSi), tungsten silicide (WSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), or other suitable compounds.

The gate via 125c and the via 145b are formed in the ILD layer 65. The gate via 125c is formed over and in contact with the gate structure 120c, and the via 145b is formed over and in contact with the source/drain contact 140b. Furthermore, the electrode 220a-1 is formed over and in contact with the gate via 125c and the via 145b. Therefore, the source/drain contact 140b is electrically connected to the gate structure 120c through the via 145b, the electrode 220a-1 and the gate via 125c. Furthermore, the electrode 220a-1 overlaps the gate structure 120c of the pull-up transistor PU2 and the drain region (i.e., the source/drain contact 140b) of the pull-up transistor PU1.

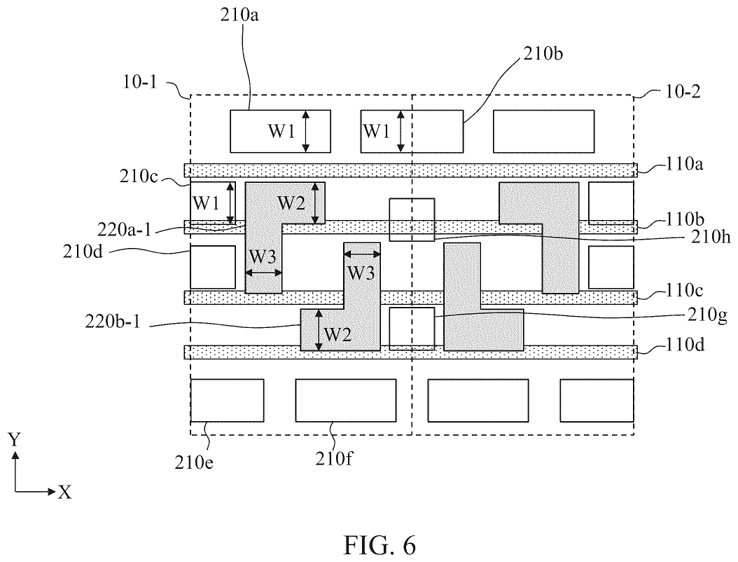

FIG. 6 illustrates the metal lines 210a through 210h and the electrodes 220a-1 and 220b-1 in the lowest metal layer of FIG. 3, in accordance with some embodiments of the disclosure. In the memory cell 10-1, the metal lines 210a through 210h are a one dimensional (1D) metal connection extending along the X-axis and have a width W1. The metal lines 210a and 210b are arranged in the same row, and the metal lines 210e and 210f are arranged in the same row. The metal lines 210c, 210d, 210h and 210g are disposed between the metal lines 210a, 210b and 210e and 210f. In some embodiments, the metal lines 210a, 210b and 210e and 210f are longer than the metal lines 210c, 210d, 210h and 210g. Moreover, the metal lines 210a, 210b and 210e and 210f do not overlap the active regions 110a through 110d, and the active regions 110a through 110d are disposed between the metal lines 210a, 210b and the metal lines 210e and 210f.

The electrodes 220a-1 and 220b-1 are disposed between the metal lines 210a through 210h. In other words, the electrodes 220a-1 and 220b-1 are surrounded by the metal lines 210a through 210h. Furthermore, the electrodes 220a-1 and 220b-1 have symmetrical shapes different from the metal lines 210a through 210h. Each of the electrodes 220a-1 and 220b-1 is a two-dimensional (2D) metal connection including a first segment and a second segment. The first segment extends along the X-axis and has a width W2, and the second segment extends along the Y-axis and has a width W3. Furthermore, the first segment of the electrode 220a-1 overlaps the active region 110b, and the second segment of the electrode 220a-1 overlaps the active regions 110b and 110c. In some embodiments, the widths W2 and W3 are different from the width W1. In some embodiments, the width W2 is different from the width W3. Each of the electrodes 220a-1 and 220b-1 overlaps at least two active regions. For example, the electrode 220a-1 overlaps the active regions 110b and 110c, and the electrode 220b-1 overlaps the active regions 110c and 110d. In some embodiments, the electrodes 220a-1 and 220b-1 both overlap the active region 110c. In some embodiments, the electrodes 220a-1 and 220b-1 do not overlap the active region 110a. In some embodiments, each area overlapping individual active region has different size for the electrodes 220a-1 and 220b-1. For example, a first area of the electrode 220a-1 overlapping the active region 110b is greater than a second area of the electrode 220a-1 overlapping the active region 110c.

In some embodiments, the metal lines 210a through 210h and the electrodes 220a-1 and 220b-1 are formed by double-patterning or multi-patterning processes in the same metal layer. For example, the metal lines 210a through 210h are formed with a first mask, and the electrodes 220a-1 and 220b-1 are formed with a second mask. In some embodiments, the electrodes 220a-1 and 220b-1 are formed after formation of the metal lines 210a through 210h. In some embodiments, the electrodes 220a-1 and 220b-1 are formed prior to formation of the metal lines 210a through 210h.

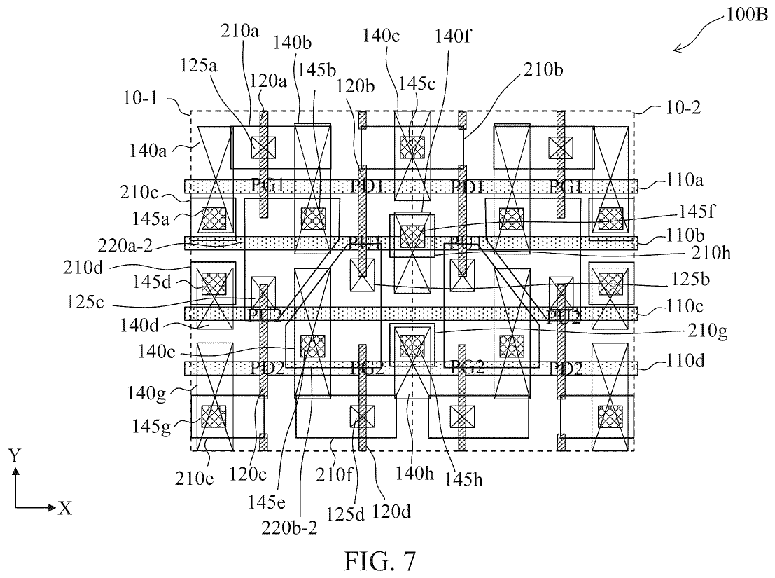

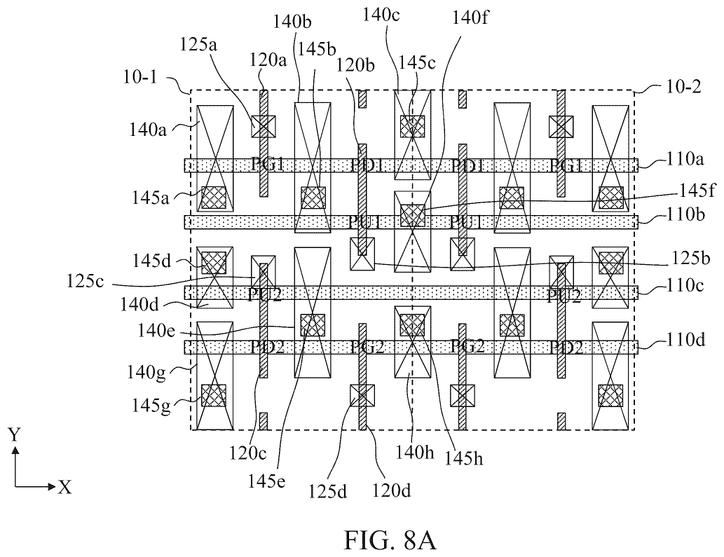

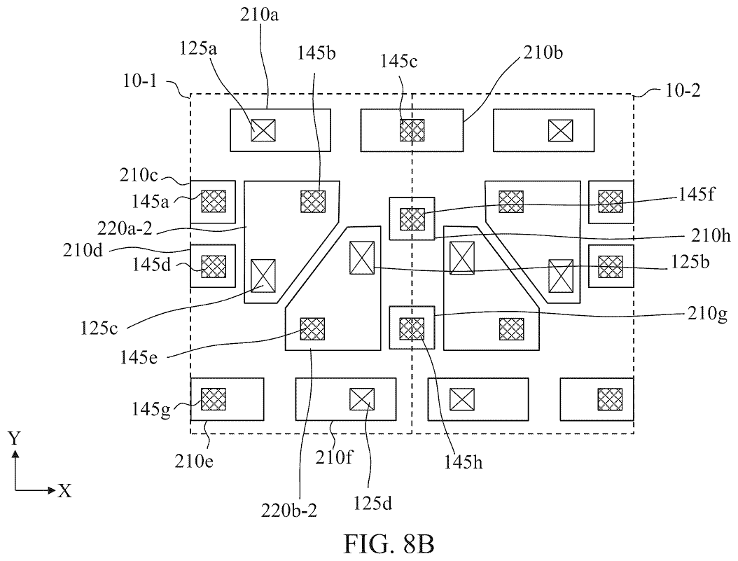

FIG. 7 illustrates a layout of a memory structure 100B including the memory cells 10-1 and 10-2, in accordance with some embodiments of the disclosure. FIG. 8A illustrates the features under a lowest metal layer and FIG. 8B illustrates the features of the interconnect structure (e.g., the interconnect structure 70 of FIG. 2) in the layout of the memory cells 10-1 and 10-2 of FIG. 7, in accordance with some embodiments of the disclosure. In this embodiment, the memory cells 10-1 and 10-2 are the single-port SRAM bit cell shown in FIG. 1. Furthermore, an outer boundary of each of the memory cells 10-1 and 10-2 is illustrated using dashed lines.

The configuration under the lowest metal layer of the memory structure 100B of FIG. 7 is the same as that of the memory structure 100A in FIG. 3. The difference in the lowest metal layer between the memory structure 100B of FIG. 7 and the memory structure 100A of FIG. 3 is that the electrodes 220a-2 and 220b-2 of the memory structure 100B of FIG. 7 are different from the electrodes 220a-1 and 220b-1 of the memory structure 100A of FIG. 3.

The electrode 220a-2 is electrically connected to the source/drain contact 140b through the via 145b and electrically connected to the gate structure 120c through the gate via 125c. The electrode 220b-2 is electrically connected to the source/drain contact 140e through the via 145e and electrically connected to the gate structure 120b through the gate via 125b. The electrode 220b-2 functions as a local connection of the node n2 in the memory cell 10-1, and no upper level interconnect structure is connected to the electrode 220b-2. The electrode 220a-2 functions as a local connection of the node n1 in the memory cell 10-1, and no upper level interconnect structure is connected to the electrode 220a-2. As described, the gate via 125c and the via 145b are not arranged in the same grid, and the gate via 125b and the via 145e are not arranged in the same grid. The electrodes 220a-2 and 220b-2 are configured to provide an oblique connection, to increase the SRAM density enhancement for pitch and reduced cell height. The electrode 220a-2 overlaps the gate structures 120a and 120c arranged in the same column, and the electrode 220b-2 overlaps the gate structures 120b and 120d arranged in the same column.

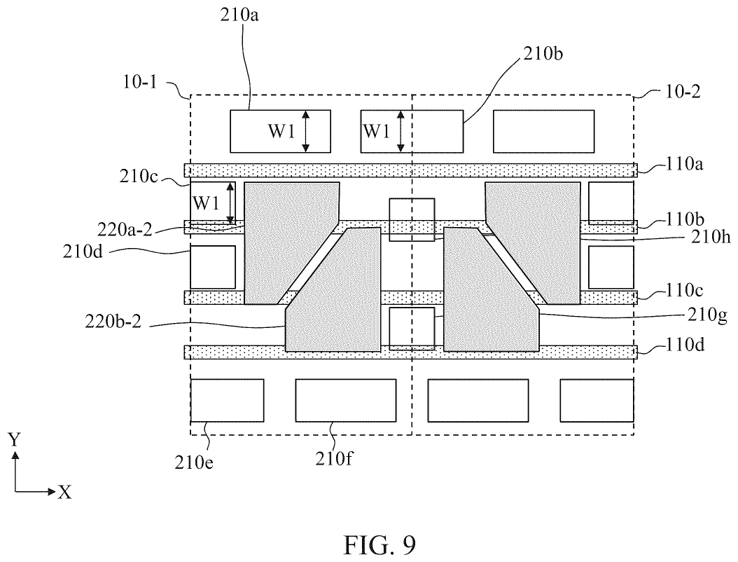

FIG. 9 illustrates the metal lines 210a through 210h and the electrodes 220a-2 and 220b-2 in the lowest metal layer of FIG. 7, in accordance with some embodiments of the disclosure. In the memory cell 10-1, the metal lines 210a through 210h extend along the X-axis and have a width W1. The metal lines 210c, 210d, 210h and 210g are disposed between the metal lines 210a, 210b and 210e and 210f. In some embodiments, the metal lines 210a, 210b and 210e and 210f are longer than the metal lines 210c, 210d, 210h and 210g. Moreover, the metal lines 210a, 210b and 210e and 210f do not overlap the active regions 110a through 110d, and the active regions 110a through 110d are disposed between the metal lines 210a, 210b and the metal lines 210e and 210f.

The electrodes 220a-2 and 220b-2 are disposed between the metal lines 210a through 210h. In other words, the electrodes 220a-2 and 220b-2 are surrounded by the metal lines 210a through 210h. Furthermore, the electrodes 220a-2 and 220b-2 have symmetrical shapes. Each of the electrodes 220a-2 and 220b-2 is pentagonal from a top view. Each of the electrodes 220a-2 and 220b-2 overlaps at least two active regions. For example, the electrode 220a-2 overlaps the active regions 110b and 110c, and the electrode 220b-2 overlaps the active regions 110b, 110c and 110d. In some embodiments, the electrodes 220a-2 and 220b-2 both overlap the active regions 110b and 110c. In some embodiments, the electrodes 220a-2 and 220b-2 do not overlap the active region 110a. In some embodiments, each area overlapping individual active region has a different size for electrodes 220a-2 and 220b-2. For example, a first area of the electrode 220a-2 overlapping the active region 110b is larger than a second area of the electrode 220a-2 overlapping the active region 110c.

In some embodiments, for each of the electrodes 220a-2 and 220b-2, the upper and lower sides are parallel to the X-axis. The right and left sides of the electrodes 220a-2 and 220b-2 are parallel to the Y-axis. Furthermore, the electrodes 220a-2 and 220b-2 have sides facing each other. In some embodiments, for each of the electrodes 220a-2 and 220b-2, five sides have different lengths.

In some embodiments, the metal lines 210a through 210h and the electrodes 220a-2 and 220b-2 are formed by double-patterning or multi-patterning processes in the same metal layer. For example, the metal lines 210a through 210h are formed with a first mask, and the electrodes 220a-2 and 220b-2 are formed with a second mask. In some embodiments, the electrodes 220a-2 and 220b-2 are formed after formation of the metal lines 210a through 210h. In some embodiments, the electrodes 220a-2 and 220b-2 are formed prior to formation of the metal lines 210a through 210h.

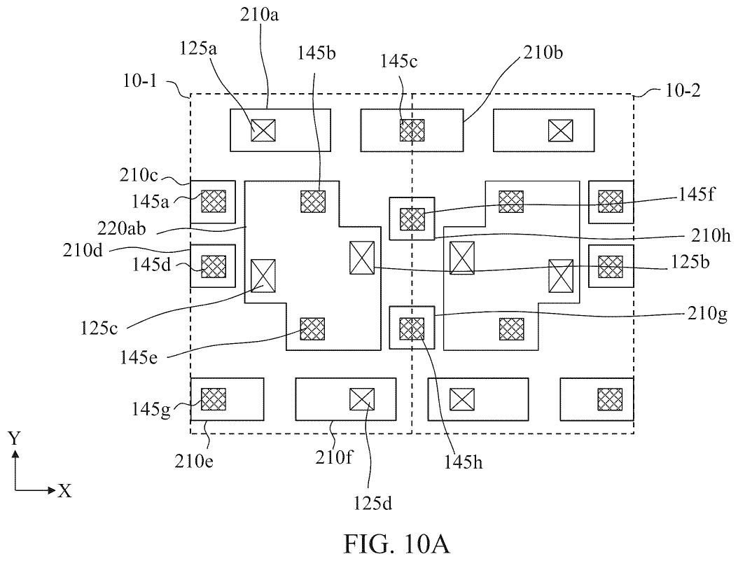

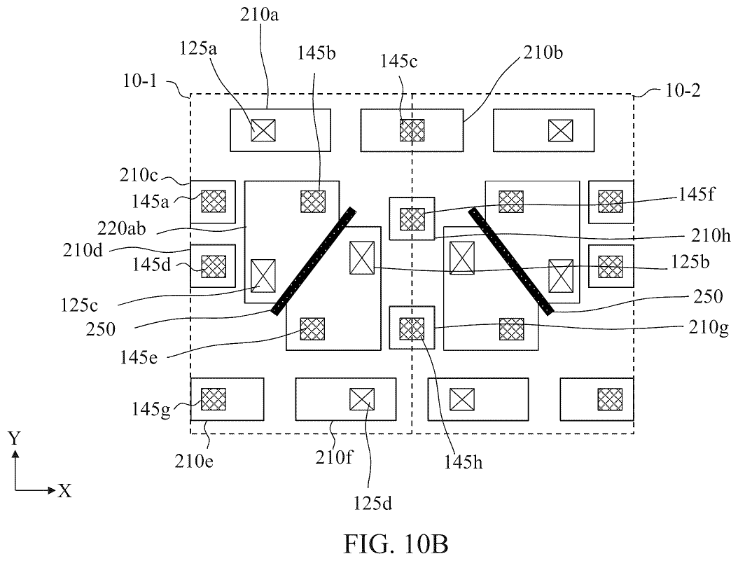

FIGS. 10A and 10B illustrate the formation of the electrodes 220a-2 and 220b-2, in accordance with some embodiments of the disclosure. First, a polygonal electrode plate 220ab is formed with the second mask, as shown in FIG. 10A. The polygonal electrode plate 220ab overlaps and contacts the gate vias 125c and 125b and the vias 145b and 145e. Next, a metal cut process is performed on the polygonal electrode plate 220ab, as shown in the metal cuts 250 of FIG. 10B. It should be understood that the metal cut 250 represents area of the semiconductor layer in which the patterned metal has been removed, for example leaving the features under the lowest metal layer. The metal cut 250 is diagonal defined by one additional mask. By performing the metal cut process on the polygonal electrode plate 220ab, the memory structure 100B has large lithography and connecting features (e.g., the vias and gate vias) to the lowest metal layer contact window.

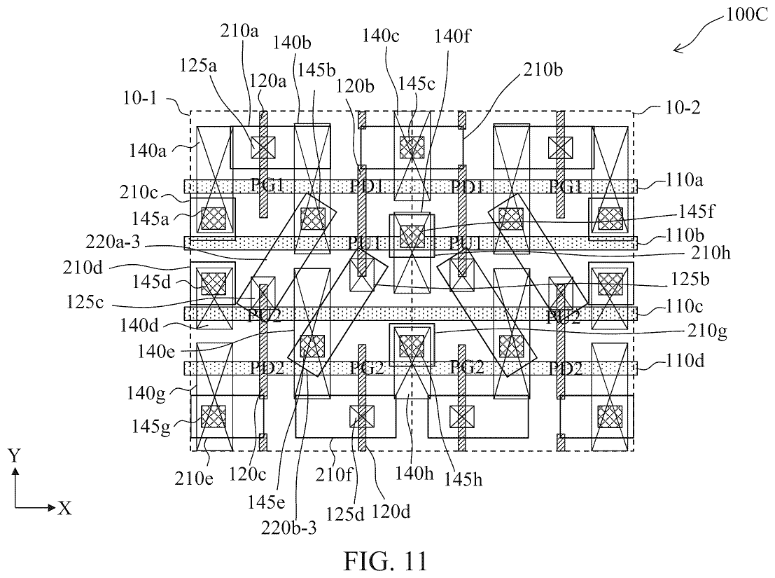

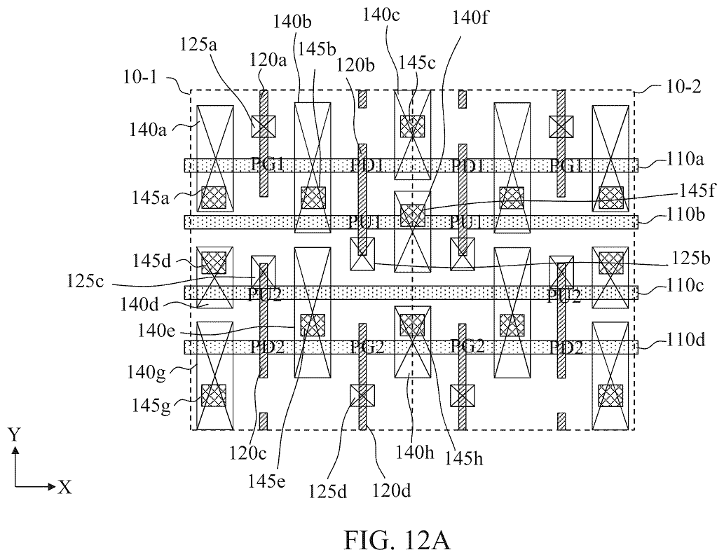

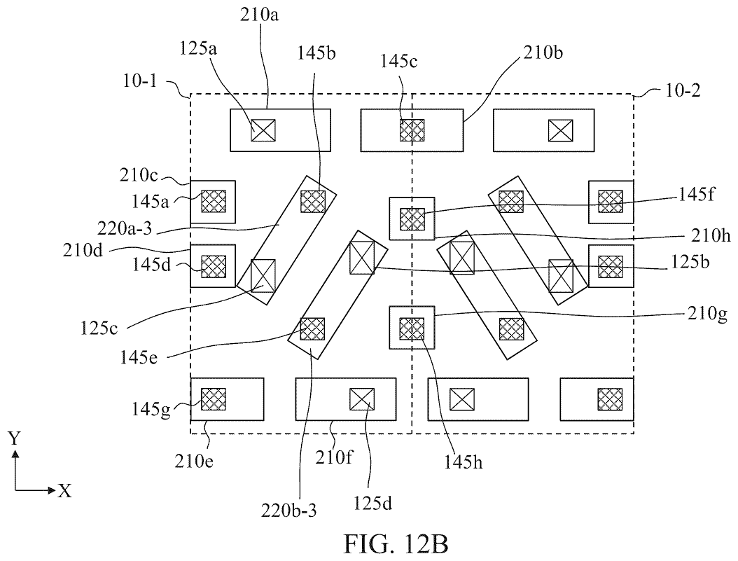

FIG. 11 illustrates a layout of a memory structure 100C including the memory cells 10-1 and 10-2, in accordance with some embodiments of the disclosure. FIG. 12A illustrates the features under a lowest metal layer and FIG. 12B illustrates the features of the interconnect structure (e.g., the interconnect structure 70 of FIG. 2) in the layout of the memory cells 10-1 and 10-2 of FIG. 11, in accordance with some embodiments of the disclosure. In this embodiment, the memory cells 10-1 and 10-2 are the single-port SRAM bit cell shown in FIG. 1. Furthermore, an outer boundary of each of the memory cells 10-1 and 10-2 is illustrated using dashed lines.

The configuration under the lowest metal layer of the memory structure 100C of FIG. 11 is the same as that of the memory structure 100A in FIG. 3. The difference in the lowest metal layer between the memory structure 100C of FIG. 11 and the memory structure 100A of FIG. 3 is that the electrodes 220a-3 and 220b-3 of the memory structure 100C of FIG. 11 are different from the electrodes 220a-1 and 220b-1 of the memory structure 100A of FIG. 3.

The electrode 220a-3 is electrically connected to the source/drain contact 140b through the via 145b and electrically connected to the gate structure 120c through the gate via 125c. The electrode 220b-3 is electrically connected to the source/drain contact 140e through the via 145e and electrically connected to the gate structure 120b through the gate via 125b. The electrode 220b-3 functions as a local connection of the node n2 in the memory cell 10-1, and no upper level interconnect structure is connected to the electrode 220b-3. The electrode 220a-3 functions as a local connection of the node n1 in the memory cell 10-1, and no upper level interconnect structure is connected to the electrode 220a-3. As described above, the gate via 125c and the via 145b are not arranged in the same grid, and the gate via 125b and the via 145e are not arranged in the same grid. The electrodes 220a-3 and 220b-3 are configured to provide an oblique connection, to increase the SRAM density enhancement for pitch and reduced cell height.

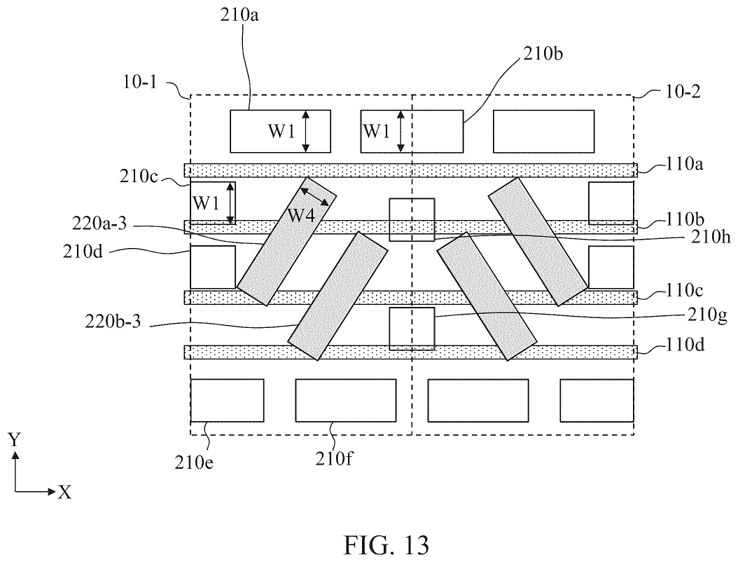

FIG. 13 illustrates the metal lines 210a through 210h and the electrodes 220a-3 and 220b-3 in the lowest metal layer of FIG. 11, in accordance with some embodiments of the disclosure. In the memory cell 10-1, the metal lines 210a through 210h extend along the X-axis and have a width W1. The metal lines 210c, 210d, 210h and 210g are disposed between the metal lines 210a, 210b and 210e and 210f. In some embodiments, the metal lines 210a, 210b and 210e and 210f are longer than the metal lines 210c, 210d, 210h and 210g. Moreover, the metal lines 210a, 210b and 210e and 210f do not overlap the active regions 110a through 110d, and the active regions 110a through 110d are disposed between the metal lines 210a, 210b and the metal lines 210e and 210f.

The electrodes 220a-3 and 220b-3 are disposed between the metal lines 210a through 210h. In other words, the electrodes 220a-3 and 220b-3 are surrounded by the metal lines 210a through 210h. Furthermore, the electrodes 220a-3 and 220b-3 have symmetrical shapes. Each of the electrodes 220a-3 and 220b-3 is a slanting line extending in a first direction and having a width W4, and the first direction is not parallel to the X-axis or Y-axis. Each of the electrodes 220a-3 and 220b-3 overlaps at least two active regions. For example, the electrode 220a-3 overlaps the active regions 110b and 110c, and the electrode 220b-3 overlaps the active regions 110b, 110c and 110d. In some embodiments, the electrodes 220a-3 and 220b-3 both overlap the active region 110c. In some embodiments, the electrodes 220a-3 and 220b-3 do not overlap the active region 110a. In some embodiments, each area overlapping individual active region has different size for the electrodes 220a-3 and 220b-3. For example, a first area of the electrode 220a-3 overlapping the active region 110b is greater than a second area of the electrode 220a-3 overlapping the active region 110c.

In some embodiments, the metal lines 210a through 210h and the electrodes 220a-3 and 220b-3 are formed by double-patterning or multi-patterning processes in the same metal layer. For example, the metal lines 210a through 210h are formed with a first mask, and the electrodes 220a-2 and 220b-2 are formed with a second mask. In some embodiments, the electrodes 220a-3 and 220b-3 are formed after formation of the metal lines 210a through 210h. In some embodiments, the electrodes 220a-3 and 220b-3 are formed prior to formation of the metal lines 210a through 210h.

By arranging the oblique connections in the lowest metal layer to provide the local connections of the nodes n1 and n2 in the memory cell 10, the SRAM density enhancement is increased for pitch and reduced cell height.

According to some embodiments, a memory structure is provided. The memory structure includes a first pull-up transistor in a first active region, a second pull-up transistor in a second active region parallel to and separated from the first active region, and an electrode overlapping the first and second active regions and configured to electrically connect a gate structure of the second pull-up transistor to a drain region of the first pull-up transistor. The electrode is formed in a metal layer closest to the first and second active regions.

According to some embodiments, a memory structure is provided. The memory structure includes a first inverter and a second inverter cross-coupled between a first pass-gate transistor and a second pass-gate transistor. Gate structures of the first and second pass-gate transistors are electrically connected to a first metal line and a second metal line, respectively. The first inverter includes a first pull-down transistor and a first pull-up transistor, and the second inverter includes a second pull-down transistor and a second pull-up transistor. A gate structure of the second pull-up transistor is electrically connected to drain regions of the first pull-up transistor, the first pull-down transistor and the first pass-gate transistor through a first electrode, and a gate structure of the first pull-up transistor is electrically connected to drain regions of the second pull-up transistor, the second pull-down transistor and the second pass-gate transistor through a second electrode. The first and second electrodes and the first and second metal lines are formed in a metal layer, and the first and second electrodes are disposed between the first and second metal lines and have symmetrical shapes different from the first and second metal lines. The first electrode overlaps the gate structure of the second pull-up transistor and the drain region of the first pull-up transistor.

According to some embodiments, a method for manufacturing a memory structure is provided. A substrate is formed. A first pass-gate transistor and a first pull-down transistor are formed in a first active region over the substrate. A first pull-up transistor is formed in a second active region over the substrate. A second pull-up transistor is formed in a third active region over the substrate. The second active region is parallel to and disposed between the first and third active regions. First and second metal lines are formed in a metal layer closest to the substrate according to a first mask, to electrically connect a gate structure of the first pass-gate transistor and a source region of the first pull-down transistor, respectively. A metal connection is formed in the metal layer according to a second mask, to electrically connect a gate structure of the second pull-up transistor and drain regions of the first pass-gate transistor, the first pull-up transistor and the first pull-down transistor. The metal connection has a shape different from the first and second metal lines, and a first area of the electrode overlapping the second active region is different from a second area of the electrode overlapping the third active region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory structure, comprising:
a first pull-up transistor in a first active region;
a second pull-up transistor in a second active region parallel to and separated from the first active region; and
an electrode overlapping the first and second active regions from a top view, and configured to electrically connect a gate structure of the second pull-up transistor to a drain region of the first pull-up transistor,
wherein the electrode is formed in a metal layer closest to the first and second active regions.

2. The memory structure of claim 1, wherein the electrode comprises a first segment extending parallel to the first active region, and a second segment extending perpendicular to the first active region.

3. The memory structure of claim 2, wherein the first and second segments overlap the first active region, and the second segment overlaps the second active region.

4. The memory structure of claim 1, wherein the electrode is pentagonal from a top view, and a first area of the electrode overlapping the first active region is different from a second area of the electrode overlapping the second active region.

5. The memory structure of claim 1, wherein the electrode extends in a first direction, and the first direction is not parallel to and not perpendicular to the first and second active regions.

6. The memory structure of claim 1, further comprising:
a first pull-down transistor in a third active region and having a drain region electrically connecting the gate structure of the second pull-up transistor through the electrode; and
a first pass-gate transistor in the third active region and having a drain region electrically connecting the gate structure of the second pull-up transistor through the electrode.

7. The memory structure of claim 6, wherein the first active region is disposed between the second and third active regions.

8. The memory structure of claim 6, wherein the electrode overlaps the gate structure of the second pull-up transistor and a gate structure of the first pass-gate transistor.

9. A memory structure, comprising:
a first inverter and a second inverter cross-coupled between a first pass-gate transistor and a second pass-gate transistor,
wherein gate structures of the first and second pass-gate transistors are electrically connected to a first metal line and a second metal line, respectively;
wherein the first inverter comprises a first pull-down transistor and a first pull-up transistor, and the second inverter comprises a second pull-down transistor and a second pull-up transistor,
wherein a gate structure of the second pull-up transistor is electrically connected to drain regions of the first pull-up transistor, the first pull-down transistor and the first pass-gate transistor through a first electrode, and a gate structure of the first pull-up transistor is electrically connected to drain regions of the second pull-up transistor, the second pull-down transistor and the second pass-gate transistor through a second electrode,
wherein the first and second electrodes and the first and second metal lines are formed in a metal layer, and the first and second electrodes are disposed between the first and second metal lines and have symmetrical shapes that are different from the first and second metal lines,
wherein the first electrode overlaps the gate structure of the second pull-up transistor and the drain region of the first pull-up transistor.

10. The memory structure of claim 9, wherein the first pull-down transistor and the first pass-gate transistor are formed in a first active region, the first pull-up transistor is formed in a second active region, the second pull-up transistor is formed in a third active region, and the second pull-down transistor and the second pass-gate transistor are formed in a fourth active region.

11. The memory structure of claim 10, wherein the first, second, third and fourth active regions are parallel to the first and second metal lines, and the second and third active regions are disposed between the first and fourth active regions.

12. The memory structure of claim 10, wherein each of the first and second electrode overlaps the second and third active regions.

13. The memory structure of claim 9, wherein each of the first and second electrodes comprises a first segment extending parallel to the first and second metal lines, and a second segment extending perpendicular to the first and second metal lines.

14. The memory structure of claim 9, wherein the first and second electrodes are pentagonal from a top view, and each of the first and second electrodes have first and second sides parallel to the first and second metal lines and third and fourth sides perpendicular to the first and second metal lines, wherein fifth sides of the first and second electrodes face to each other.

15. The memory structure of claim 9, wherein the first and second electrodes extend in a first direction, and the first direction is not parallel to and not perpendicular to the first and second metal lines.

16. A method for manufacturing a memory structure, comprising:
forming a substrate;
forming a first pass-gate transistor and a first pull-down transistor in a first active region over the substrate;
forming a first pull-up transistor in a second active region over the substrate;
forming a second pull-up transistor in a third active region over the substrate, wherein the second active region is parallel to and disposed between the first and third active regions;
forming first and second metal lines in a metal layer closest to the substrate according to a first mask, to electrically connect a gate structure of the first pass-gate transistor and a source region of the first pull-down transistor, respectively; and
forming a metal connection in the metal layer according to a second mask, to electrically connect a gate structure of the second pull-up transistor and drain regions of the first pass-gate transistor, the first pull-up transistor and the first pull-down transistor,
wherein the metal connection has a shape different from the first and second metal lines, and a first area of the metal connection overlapping the second active region is different from a second area of the metal connection overlapping the third active region.

17. The method of claim 16, wherein the metal connection comprises a first segment extending parallel to the first active region, and a second segment extending perpendicular to the first active region.

18. The method of claim 16, wherein the first and second segments overlap the second active region, and the second segment overlaps the third active region.

19. The method of claim 16, wherein forming the metal connection with the second mask in the metal layer further comprises:
forming an electrode with the second mask in the metal layer; and
performing a metal cut process on the electrode to form the metal connection.

20. The method of claim 16, wherein the metal connection extends in a first direction, and the first direction is not parallel to and not perpendicular to the first and second metal lines.
